(19) United States
(12) Patent Application Publication
(10) Pub. No.: US 2026/0261609 A1
(43) Pub. Date: Sep. 3, 2026

(54) ELECTRONIC DEVICE AND METHOD OF MANUFACTURING THE SAME

(71) Applicant: Samsung Display Co., LTD., Yongin-si (KR)

(72) Inventors: JUNGKYU LEE, Yongin-si (KR); JUEYOUN PARK, Yongin-si (KR)

(21) Appl. No.: 19/390,602

(22) Filed: Nov. 16, 2025

(30) Foreign Application Priority Data
Feb. 28, 2025 (KR) 10-2025-0026354
Apr. 11, 2025 (KR) 10-2025-0047486

(51) Int. Cl. H04M 1/02; H10H 29/01; H10H 29/854; H10K 59/12; H10K 59/80; H10K 102/00

(52) U.S. Cl. CPC H04M 1/0268; H10K 59/8722; H10K 59/873; H04M 1/0214; H04M 1/0235; H10H 29/0362; H10H 29/854; H10K 59/1201; H10K 2102/311

(57) ABSTRACT

An electronic device includes a display module including a deformation part capable of folding, rolling, or sliding and a non-deformation part next (adjacent) to the deformation part and a window member disposed on the display module. The window member includes a synthetic resin film and a first adhesive layer and a second adhesive layer arranged between the display module and the synthetic resin film. The first adhesive layer includes a post-curable adhesive and has a Young's modulus of 0.1 megapascal (MPa) to 1 MPa at the room temperature, and the second adhesive layer includes a low hardness adhesive having a hardness smaller than that of the post-curable adhesive.

This application claims priority to Korean Patent Application No. 10-2025-0026354, filed on Feb. 28, 2025, and Korean Patent Application No. 10-2025-0047486, filed on Apr. 11, 2025, and all the benefits accruing therefrom under 35 U.S.C. § 119, the contents of which in their entirety are herein incorporated by reference.

### BACKGROUND

### 1. Field

Embodiments of the disclosure described herein relate to an electronic device including a window member including a synthetic resin film, a first adhesive layer, and a second adhesive layer, and a method of manufacturing an electronic device.

### 2. Description of the Related Art

Various electronic devices such as televisions, mobile phones, tablet computers, and game consoles are being developed. Recently, flexible electronic devices including foldable, rollable, and slidable flexible display panels are being developed. Unlike rigid electronic devices, the flexible electronic devices may be folded or rolled. The flexible electronic devices having variously changed shapes may be carried without being restricted by a screen size according to the related art, thereby improving user convenience. Members for maintaining flexible operation reliability are desired in flexible electronic devices.

### SUMMARY

Embodiments of the disclosure provide an electronic device exhibiting excellent folding, rolling, and sliding reliability and excellent display quality.

Embodiments of the disclosure also provide a method of manufacturing an electronic device exhibiting excellent manufacturing efficiency and excellent processability.

In an embodiment of the disclosure, an electronic device includes a display module including a deformation part capable of folding, rolling, or sliding and a non-deformation part next (adjacent) to the deformation part and a window member disposed on the display module, wherein the window member includes a synthetic resin film and a first adhesive layer and a second adhesive layer arranged between the display module and the synthetic resin film, the first adhesive layer includes a post-curable adhesive and has a Young's modulus of 0.1 megapascal (MPa) to 1 MPa at the room temperature, and the second adhesive layer includes a low hardness adhesive having a hardness smaller than that of the post-curable adhesive.

In an embodiment, surface quality may be smaller than or equal to 0.3.

In an embodiment, the synthetic resin film may have a Young's modulus of 0.5 gigapascal (GPa) to 10 GPa at the room temperature.

In an embodiment, the synthetic resin film may include at least one of an acrylic resin, an epoxy resin, and a siloxane resin.

In an embodiment, a crosslinking degree of the first adhesive layer may be greater than or equal to 90%.

In an embodiment, the second adhesive layer may have a Young's modulus of 0.01 MPa to 0.1 MPa at the room temperature.

In an embodiment, the synthetic resin film may be disposed on the first adhesive layer, and the first adhesive layer may be disposed on the second adhesive layer.

In an embodiment, the synthetic resin film may be disposed on the second adhesive layer, and the second adhesive layer may be disposed on the first adhesive layer.

In an embodiment, the second adhesive layer may include a first sub-adhesive layer and a second sub-adhesive layer, the synthetic resin film may be disposed on the first sub-adhesive layer, the first sub-adhesive layer may be disposed on the first adhesive layer, and the first adhesive layer may be disposed on the second sub-adhesive layer.

In an embodiment, the synthetic resin film may contact the first adhesive layer or the second adhesive layer, and the first adhesive layer and the second adhesive layer may contact each other.

In an embodiment, the window member may have a thickness of 25 micrometers (μm) to 100 μm.

In an embodiment, the electronic device may further include at least one of a processor, a memory, and a power module.

In an embodiment of the disclosure, a method of manufacturing an electronic device includes preparing a display module including a deformation part capable of folding, rolling, or sliding and a non-deformation part next (adjacent) to the deformation part, forming a preliminary window member including a synthetic resin film, a first preliminary adhesive layer, and a second adhesive layer, providing the preliminary window member onto the display module, and forming a window member including the synthetic resin film, a first adhesive layer, and the second adhesive layer by radiating second light to the preliminary window member, wherein the forming of the preliminary window member includes preparing a substrate, providing a post-curable adhesive and a low hardness adhesive having a hardness smaller than that of the post-curable adhesive onto the substrate, providing the synthetic resin film onto the post-curable adhesive and the low hardness adhesive, and forming the first preliminary adhesive layer and the second adhesive layer by radiating first light to the post-curable adhesive and the low hardness adhesive, the first adhesive layer includes the post-curable adhesive and has a Young's modulus of 0.1 MPa to 1 MPa at the room temperature, and the second adhesive layer includes the low hardness adhesive.

In an embodiment, the providing of the post-curable adhesive may be performed after the providing of the low hardness adhesive.

In an embodiment, the providing of the low hardness adhesive may be performed after the providing of the post-curable adhesive.

In an embodiment, the post-curable adhesive may include a first sub-post-curable adhesive and a second sub-post-curable adhesive, the providing of the low hardness adhesive may be performed after providing of the first sub-post-curable adhesive, and providing of the second sub-post-curable adhesive may be performed after the providing of the low hardness adhesive.

### BRIEF DESCRIPTION OF THE DRAWINGS

The above and other embodiments, advantages and features of the disclosure will become apparent by describing in detail embodiments thereof with reference to the accompanying drawings.

FIG. 1 is a block diagram of an embodiment of an electronic device.

FIG. 2 is a view illustrating an embodiment of an electronic device.

FIG. 3A is a perspective view illustrating an embodiment of the electronic device.

FIG. 3B is a perspective view illustrating an embodiment of the electronic device.

FIG. 3C is a plan view illustrating an embodiment of the electronic device.

FIG. 3D is a perspective view illustrating an embodiment of the electronic device.

FIG. 4 is an exploded perspective view illustrating an embodiment of the electronic device.

FIG. 5 is a cross-sectional view illustrating a portion corresponding to line I-I′ of FIG. 4.

FIG. 6A is a cross-sectional view illustrating an embodiment of a portion of the electronic device.

FIG. 6B is a cross-sectional view illustrating an embodiment of a portion of the electronic device.

FIG. 7 is a cross-sectional view illustrating an embodiment of a portion corresponding to line II-II′ of FIG. 4.

FIG. 8A is a perspective view illustrating an embodiment of the electronic device.

FIG. 8B is a perspective view illustrating an embodiment of the electronic device.

FIG. 9 is a cross-sectional view illustrating a portion corresponding to line III-III′ of FIG. 8A.

FIG. 10A is a perspective view illustrating an embodiment of the electronic device.

FIG. 10B is a perspective view illustrating an embodiment of the electronic device.

FIG. 11A is a perspective view illustrating an embodiment of a portion of the electronic device.

FIG. 11B is a perspective view illustrating an embodiment of a portion of the electronic device.

FIG. 12A is a flowchart illustrating an embodiment of a method of manufacturing an electronic device.

FIG. 12B is a flowchart illustrating an embodiment of a method of manufacturing an electronic device.

FIG. 13A is a schematic view illustrating an embodiment of an operation of manufacturing an electronic device.

FIG. 13B is a schematic view illustrating an embodiment of an operation of manufacturing an electronic device.

FIG. 13C is a schematic view illustrating an embodiment of an operation of manufacturing an electronic device.

FIG. 13D is a schematic view illustrating an embodiment of an operation of manufacturing an electronic device.

FIG. 13E is a schematic view illustrating an embodiment of an operation of manufacturing an electronic device.

FIG. 13F is a schematic view illustrating an embodiment of an operation of manufacturing an electronic device.

FIG. 13G is a schematic view illustrating an embodiment of an operation of manufacturing an electronic device.

FIG. 13H is a schematic view illustrating an embodiment of an operation of manufacturing an electronic device.

### DETAILED DESCRIPTION

In the specification, the expression that a first component (or area, layer, part, portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The expression “and/or” includes one or more combinations which associated components are capable of defining.

Although the terms “first,” “second,” etc., may be used to describe various components, the components should not be limited by the terms. The terms are used only to distinguish one component, one part, one area, one layer or one portion from another component, another part, another area, another layer or another portion. For example, without departing from the scope of the disclosure, a first component, a first part, a first area, a first layer, or a first portion may be referred to as a second component, a second part, a second area, a second layer, or a second portion, and similarly, the second component, the second part, the second area, the second layer, or the second portion may also be referred to as the first component, the first part, the first area, the first layer, or the first portion. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the disclosure belongs. Furthermore, terms such as terms defined in the dictionaries commonly used should be interpreted as having a meaning consistent with the meaning in the context of the related technology and should not be interpreted in overly ideal or overly formal meanings unless explicitly defined herein.

Hereinafter, an embodiment of the disclosure will be described with reference to the accompanying drawings.

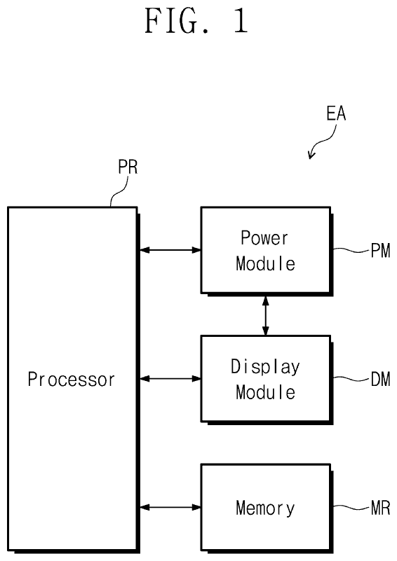

FIG. 1 is a block diagram of an embodiment of an electronic device. An electronic device EA may include a display module DM. The electronic device EA may further include at least one of a processor PR, a memory MR, and a power module PM. Referring to FIG. 1, the electronic device EA in an embodiment may include the display module DM, the processor PR, the memory MR, and the power module PM.

The processor PR may include at least one of a central processing unit (“CPU”), an application processor (“AP”), a graphic processing unit (“GPU”), a communication processor (“CP”), an image signal processor (“ISP”), and a controller.

Data information desired for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen.

The power module PM may include a power supply module such as a power adapter or a battery device and a power conversion module that converts power supplied by the power supply module to generate power desired for operating the electronic device EA.

At least one of the components of the electronic device EA may be included in a display device in an embodiment, which will be described below. Further, some of individual modules functionally included inside one module may be included inside the display device, and remaining (the other) modules thereof may be provided separately from the display device. In an embodiment, the display device may include the display module DM, and the processor PR, the memory MR, and the power module PM may be provided in the form of other devices in the electronic device EA rather than the display device, for example.

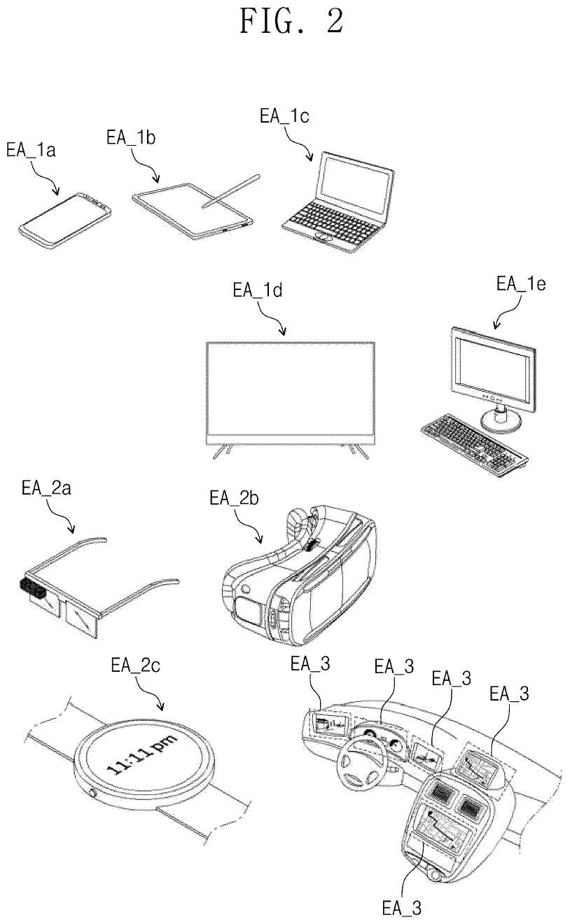

FIG. 2 is a schematic view of an embodiment of the electronic device. Referring to FIG. 2, various electronic devices to which the display device is applied in an embodiment may include an image display electronic device such as a smartphone EA_1a, a tablet personal computer (“PC”) EA_1b, a laptop computer EA_1c, a television (“TV”) EA_1d, and a desk monitor EA_1e, a wearable electronic device including a display module such as a smart glasses EA_2a, a head mounted display EA_2b, and a smart watch EA_2c, and a vehicle electronic device EA_3 including a display module such as an instrument panel, a center fascia, a center information display (“CID”) disposed on a dashboard, and a room mirror display of a vehicle.

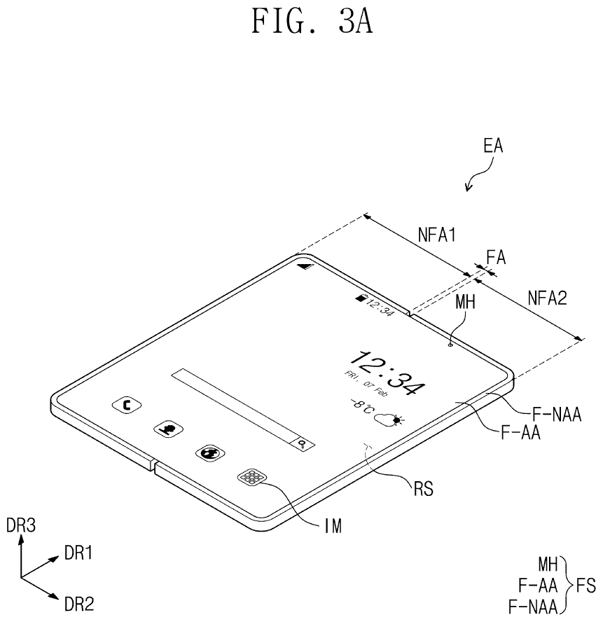

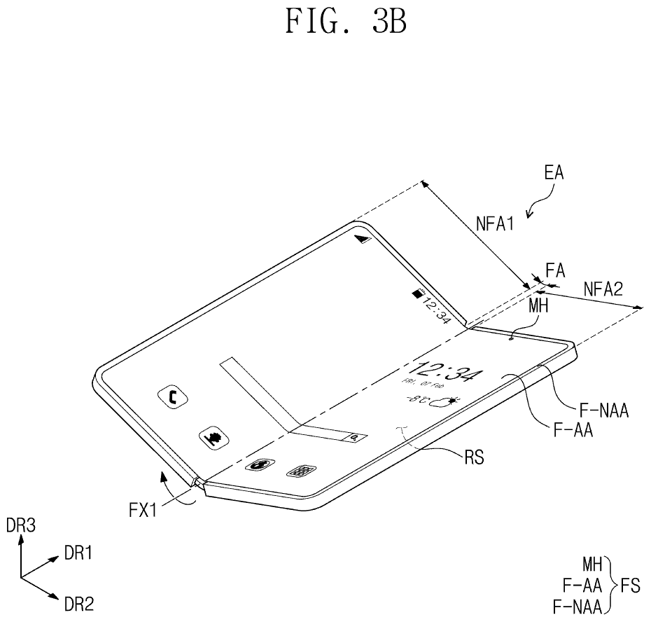

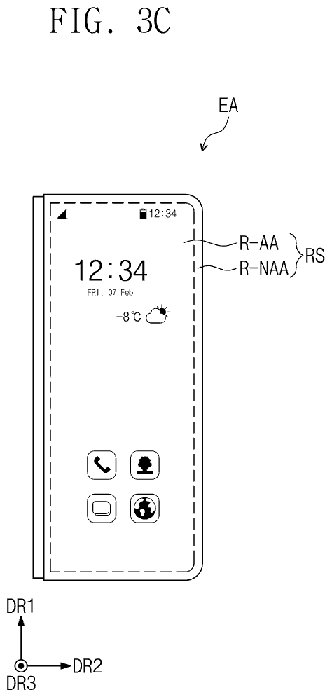

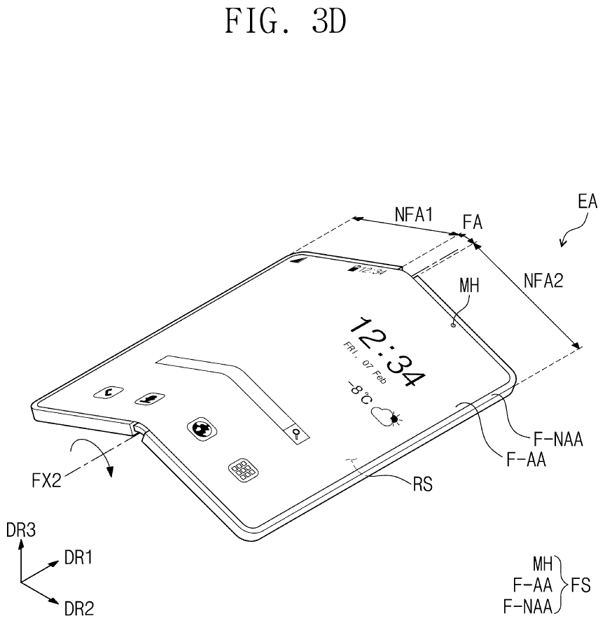

FIG. 3A is a perspective view of a state in which the electronic device EA in an embodiment is unfolded. The electronic device EA in an embodiment may be a device that is activated according to an electrical signal. In an embodiment, the electronic device EA may be a smartphone, a tablet computer, a vehicle navigation system, a game console, a portable electronic device, or a wearable device, for example, but the disclosure is not limited thereto. FIG. 3A or the like illustrates, as one of the embodiments, that the electronic device EA is a smartphone.

The electronic device EA may include a first display surface FS defined by a first direction axis DR1 and a second direction axis DR2 intersecting the first direction axis DR1. The electronic device EA may provide an image IM to a user through the first display surface FS. The electronic device EA may display the image IM in a third direction axis DR3 to the first display surface FS parallel to the first direction axis DR1 and the second direction axis DR2. The image IM may include a dynamic image and a static image.

In the specification, the first direction axis DR1 and the second direction axis DR2 may be perpendicular to each other, and the third direction axis DR3 may be a normal direction to a plane defined by the first direction axis DR1 and the second direction axis DR2. A thickness direction of the electronic device EA may be a direction parallel to the third direction axis DR3. The thickness direction of the electronic device EA may use the same reference numeral as that of the third direction axis DR3. A front surface (or an upper surface) and a rear surface (or a lower surface) may be opposite to each other in the third direction axis DR3, and a normal direction of each of the front surface (or the upper surface) and the rear surface (or the lower surface) may be parallel to the third direction axis DR3. The front surface (or the upper surface) means a surface adjacent to the first display surface FS, and the rear surface (or the lower surface) means a surface spaced apart from the first display surface FS. Further, the rear surface (or the lower surface) means a surface close to a second display surface RS, which will be described below. An upper side means a direction closer to the first display surface FS, and a lower side means a direction away from the first display surface FS.

A cross section means a surface parallel to the third direction axis (also referred to as a thickness direction) DR3, and a plane means a surface perpendicular to the thickness direction DR3. The plane means the plane defined by the first direction axis DR1 and the second direction axis DR2.

The directions indicated by the first direction axis DR1, the second direction axis DR2, and the third direction axis DR3 described in the specification are relative concepts and may be changed to other directions. Further, the directions indicated by the first direction axis DR1, the second direction axis DR2, and the third direction axis DR3 may be described as a first direction, a second direction, and a third direction, and the same reference numerals may be used therefor.

The electronic device EA may sense an external input applied from the outside. The external input may include various types of inputs provided from the outside of the electronic device EA. In an embodiment, the external input may include a contact by a part of a body of the user such as a hand as well as an external input (e.g., hovering) applied close to the electronic device EA or next (adjacent) to the electronic device EA at a constant distance, for example. Further, the external input may have various forms such as a force, a pressure, a temperature, and light.

The electronic device EA may include the first display surface FS and the second display surface RS. The first display surface FS may include a first active area F-AA and a first peripheral area F-NAA. The first display surface FS may further include a sub-area MH. The second display surface RS may be defined as a surface facing at least a portion of the first display surface FS. That is, the second display surface RS may be defined as a portion of the rear surface of the electronic device EA.

The first active area F-AA may be an area that is activated according to an electrical signal. The first active area F-AA may be an area in which the image IM is displayed and various forms of external inputs may be sensed.

The first peripheral area F-NAA may be next (adjacent) to the first active area F-AA. A light transmittance of the first peripheral area F-NAA may be lower than a light transmittance of the first active area F-AA. The first peripheral area F-NAA may have a color. The first peripheral area F-NAA may surround the first active area F-AA. Accordingly, a shape of the first active area F-AA may be defined substantially by the first peripheral area F-NAA. However, this is one of the embodiments, and the first peripheral area F-NAA may be disposed next (adjacent) to only one side of the first active area F-AA or may be omitted.

The sub-area MH may sense an external subject received through the display surfaces FS and RS or provide a sound signal such as voice to the outside through the display surfaces FS and RS. An optical signal such as visible light or infrared light may be moved to the sub-area MH.

Various electronic modules may be disposed to correspond to the sub-area MH. In an embodiment, the electronic module may include at least one of a camera, a speaker, a light sensing sensor, and a heat sensing sensor, for example. The electronic device EA may include the electronic module that captures an external image through visible light passing through the sub-area MH or determines accessibility of an external object through infrared light. The electronic module may include a plurality of components, and the disclosure is not limited to an embodiment.

The sub-area MH may be disposed inside the first active area F-AA. However, this is one of the embodiments, and the disclosure is not limited to an embodiment. In an embodiment, the sub-area MH may be surrounded by the first peripheral area F-NAA or may be surrounded by the first active area F-AA and the first peripheral area F-NAA, for example. FIG. 3A or the like illustrate one sub-area MH, but the sub-area MH may be provided as a plurality of sub-areas MH.

The electronic device EA in an embodiment may include at least one folding area FA and a plurality of non-folding areas NFA1 and NFA2 extending from the folding area FA. In an embodiment, the first non-folding area NFA1, the folding area FA, and the second non-folding area NFA2 may be defined in the second direction axis (also referred as a second direction) DR2. In the electronic device EA in an embodiment, the folding area FA may be disposed between the first non-folding area NFA1 and the second non-folding area NFA2 in the second direction DR2. The first non-folding area NFA1 may be next (adjacent) to one side of the folding area FA, and the second non-folding area NFA2 may be next (adjacent) to an opposite side of the folding area FA, for example. In an embodiment, the first non-folding area NFA1 may be disposed on one side of the folding area FA in the second direction DR2, and the second non-folding area NFA2 may be disposed on an opposite side of the folding area FA in the second direction DR2.

FIG. 3A or the like illustrate an embodiment of the electronic device EA including the one folding area FA, but the disclosure is not limited thereto, and a plurality of folding areas may be defined in the electronic device EA. In an embodiment, the electronic device in an embodiment may include two or more folding areas and may include three or more non-folding areas disposed with the folding areas interposed therebetween, for example.

FIG. 3B is a perspective view illustrating an embodiment of a folding operation of the electronic device EA. FIG. 3C is a plan view of a state in which the electronic device EA in an embodiment is folded. FIG. 3D is a perspective view illustrating a folding operation of the electronic device EA.

Referring to FIG. 3B, the electronic device EA in an embodiment may be folded about a first folding axis FX1 extending in the first direction axis (also referred to as a first direction) DR1. In a state in which the electronic device EA is folded, the folding area FA may have a curvature and a radius of curvature. The electronic device EA may be folded about the first folding axis FX1 so that the first non-folding area NFA1 and the second non-folding area NFA2 face each other and may be changed into an in-folding state to prevent the first display surface FS from being exposed to the outside.

FIG. 3C may be a plan view illustrating an embodiment of the electronic device EA in the in-folding state. Referring to FIG. 3C, in a state in which the electronic device EA in an embodiment is in the in-folding state, the second display surface RS may be visually recognized by the user. In this case, the second display surface RS may include a second active area R-AA that displays an image. The second active area R-AA may be an area that is activated according to an electrical signal. The second active area R-AA may be an area on which an image is displayed and various types of external inputs may be sensed.

A second peripheral area R-NAA may be next (adjacent) to the second active area R-AA. A light transmittance of the second peripheral area R-NAA may be lower than a light transmittance of the second active area R-AA. The second peripheral area R-NAA may have a color. The second peripheral area R-NAA may surround the second active area R-AA. Although not illustrated, the electronic device EA may further include a sub-area in which an electronic module including various components is disposed even on the second display surface RS, but the disclosure is not limited to an embodiment.

Referring to FIG. 3D, the electronic device EA in an embodiment may be folded about a second folding axis FX2 extending in the first direction DR1. The electronic device EA may be folded about the second folding axis FX2 and changed into an out-folding state so that the first display surface FS is exposed to the outside. In an embodiment, the electronic device EA may mutually repeat an in-folding operation or an out-folding operation from an unfolding operation, but the disclosure is not limited thereto.

Although FIGS. 3A to 3D illustrate, as one of the embodiments, the folding about the one folding axis FX1 or FX2, in the electronic device EA in an embodiment, the number of folding axes and the number of non-folding areas according thereto are not limited thereto. In an embodiment, the electronic device EA may be folded about a plurality of folding axes so that the first display surface FS and the second display surface RS are folded to partially face each other, for example. Further, it is illustrated that the first folding axis FX1 and the second folding axis FX2 are parallel to long sides of the electronic device EA, but the disclosure is not limited thereto, and the first folding axis FX1 and the second folding axis FX2 may be parallel to short sides of the electronic device EA.

In the electronic device EA, as illustrated in FIG. 3C, the first non-folding area NFA1 and the second non-folding area NFA2 may be defined as portions having the display surfaces FS and RS parallel to the plane defined by the first direction axis DR1 and the second direction axis DR2 in a folded state, and the folding area FA may be defined as an area between the first non-folding area NFA1 and the second non-folding area NFA2. The folding area FA may include a curved surface that is curved to have a curvature in a folded state.

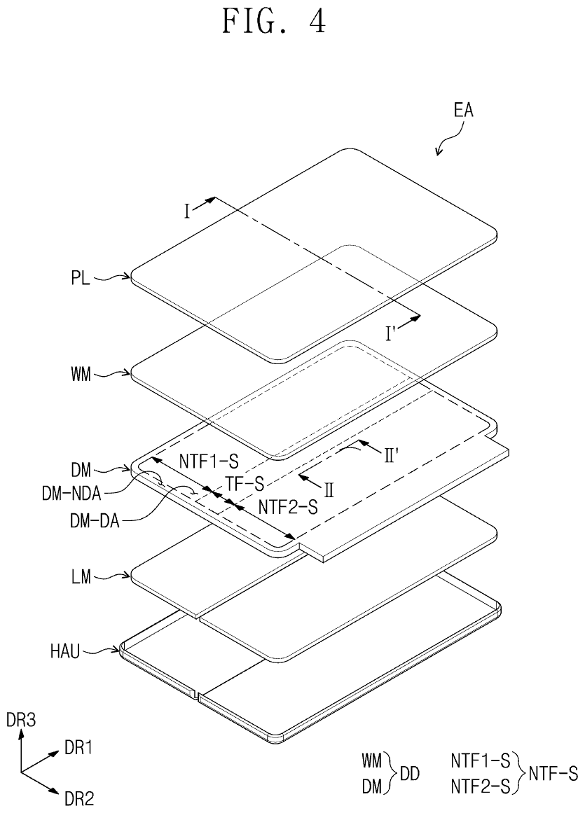

FIG. 4 is an exploded perspective view illustrating an embodiment of the electronic device EA. Referring to FIG. 4, the electronic device EA may include a display device DD. The display device DD may include the display module DM and a window member WM disposed on the display module DM. Further, the electronic device EA may further include a lower module LM disposed under the display module DM, a protective layer PL disposed on the window member WM, and a housing HAU accommodating the display module DM and the lower module LM.

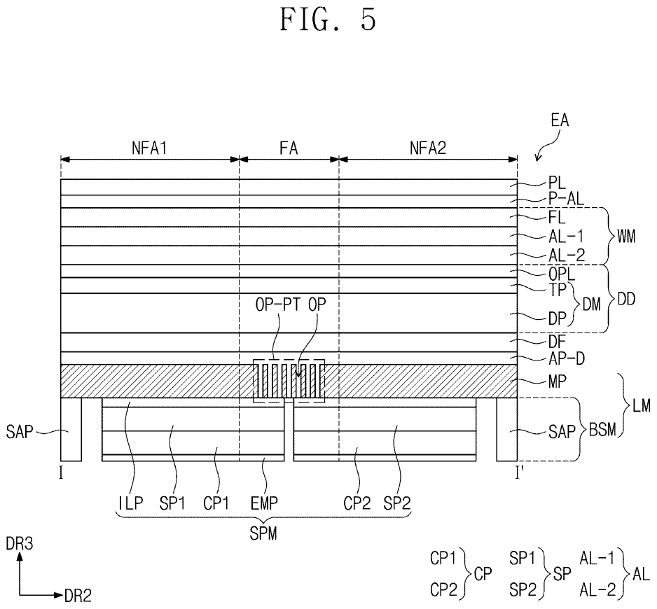

The window member WM may be folded about at least one folding axis FX1 and FX2 (refer to FIGS. 3B and 3D). The window member WM may include a synthetic resin film FL (refer to FIG. 5) and a window adhesive layer AL (refer to FIG. 5), which will be described below. The window adhesive layer AL (refer to FIG. 5) may include a first adhesive layer AL-1 (refer to FIG. 5) and a second adhesive layer AL-2 (refer to FIG. 5). The window member WM including the synthetic resin film FL (refer to FIG. 5), the first adhesive layer AL-1 (refer to FIG. 5), and the second adhesive layer AL-2 (refer to FIG. 5) in an embodiment may be easily repeatedly folded and unfolded and may exhibit improved surface quality. Accordingly, the electronic device EA including the window member WM in an embodiment may exhibit excellent reliability and excellent display quality.

The image IM (refer to FIG. 3A) generated in the display module DM may be provided to the user through the window member WM. The display module DM may display an image according to an electrical signal and transmit/receive information on an external input. A display area DM-DA and a non-display area DM-NDA may be defined in the display module DM.

The display area DM-DA may be defined as an area that emits an image provided from the display module DM. The display area DM-DA of the display module DM may correspond to at least a portion of the first active area F-AA (refer to FIG. 3A).

A driving circuit, a driving wiring line, or the like for driving the display area DM-DA may be disposed in the non-display area DM-NDA. The non-display area DM-NDA may be next (adjacent) to the display area DM-DA. In an embodiment, the non-display area DM-NDA may surround the display area DM-DA, for example. However, this is one of the embodiments, the non-display area DM-NDA may be defined in various shapes, and the disclosure is not limited to an embodiment.

The display module DM may be folded about the folding axes FX1 and FX2 (refer to FIGS. 3B and 3D). The display module DM may include a deformation part TF-S and a non-deformation part NTF-S next (adjacent) to the deformation part TF-S. The non-deformation part NTF-S may include a first non-deformation portion NTF1-S and a second non-deformation portion NTF2-S. The deformation part TF-S may be a part capable of a folding operation.

The deformation part TF-S may be a part corresponding to the folding area FA (refer to FIG. 3A), and the non-deformation portions NTF1-S and NTF2-S may be portions corresponding to the non-folding areas NFA1 and NFA2 (refer to FIG. 3A). In the specification, a folding part of the display module DM is also referred to as the deformation part TF-S, and a first non-folding part and a second non-folding part of the display module DM are also referred to as the first non-deformation portion NTF1-S and the second non-deformation portion NTF2-S, respectively.

The deformation part TF-S may correspond to a part that is folded about the folding axes FX1 and FX2 (refer to FIGS. 3B and 3D). The deformation part TF-S may be disposed between the first non-deformation portion NTF1-S and the second non-deformation portion NTF2-S in the second direction DR2. The first non-deformation portion NTF1-S may be next (adjacent) to one side of the deformation part TF-S, and the second non-deformation portion NTF2-S may be next (adjacent) to an opposite side of the deformation part TF-S. The first non-deformation portion NTF1-S may be next (adjacent) to the one side of the deformation part TF-S in the second direction DR2, and the second non-deformation portion NTF2-S may be next (adjacent) to an opposite side of the deformation part TF-S in the second direction DR2. The first non-deformation portion NTF1-S may be a portion corresponding to the first non-folding area NFA1 (refer to FIG. 3A). The second non-deformation portion NTF2-S may be a portion corresponding to the second non-folding area NFA2 (refer to FIG. 3A).

The housing HAU may include a material having a relatively high rigidity. In an embodiment, the housing HAU may include a plurality of frames and/or plates including or consisting of glass, plastic, or metal, for example. The housing HAU may provide an accommodation space. The display module DM may be accommodated inside the accommodation space and protected from an external impact.

FIG. 5 is a cross-sectional view illustrating a portion corresponding to line I-I′ of FIG. 4. FIG. 5 may be a cross-sectional view illustrating an embodiment of the electronic device EA. In FIG. 5, for convenience of description, the housing HAU (refer to FIG. 4) is omitted.

Referring to FIG. 5, the electronic device EA may further include an upper adhesive layer P-AL, a lower adhesive layer AP-D, and a lower protective film DF. The lower module LM, the lower adhesive layer AP-D, and the lower protective film DF may be arranged between the display module DM and the housing HAU (refer to FIG. 4).

The lower module LM may be disposed below the display module DM. The lower module LM may include a support plate MP and a lower support member BSM. A configuration of the lower module LM illustrated in FIG. 5 is one of the embodiments, and a combination of components included in the lower module LM in the electronic device EA in an embodiment may be changed depending on a size of the electronic device EA, a shape of the electronic device EA, or operating characteristics of the electronic device EA.

The support plate MP may include a metal material or a polymer material. In an embodiment, the support plate MP may be formed to include stainless steel, aluminum, or any alloys thereof. Unlike this, the support plate MP may include or consist of a polymer material. A plurality of openings OP may be defined in the support plate MP. The support plate MP may include an opening pattern OP-PT in which the plurality of openings OP are defined. The opening pattern OP-PT may be formed in the folding area FA.

The lower support member BSM may include a support member SPM and a filling part SAP. On a plane, the support member SPM may overlap most areas of the display module DM. The filling part SAP may be disposed outside the support member SPM and may overlap an exterior of the display module DM.

The support member SPM may include at least one of a support layer SP, a cushion layer CP, a shielding layer EMP, and an inter-joining layer ILP. A configuration of the support member SPM illustrated in FIG. 5 is one of the embodiments, and the disclosure is not limited thereto. In an embodiment, some of the support layer SP, the cushion layer CP, the shielding layer EMP, and the inter-joining layer ILP may be omitted, a laminated order thereof may be modified to a different order from that of FIG. 5, or an additional component in addition to the illustrated components may be further included in the support member SPM, for example.

The support layer SP may include a metal material or a polymer material. The support layer SP may be disposed below the support plate MP. In an embodiment, the support layer SP may be a thin metal substrate, for example. The support layer SP may include a first sub-support layer SP1 and a second sub-support layer SP2 spaced apart from each other in the second direction DR2. The first sub-support layer SP1 and the second sub-support layer SP2 may be spaced apart from each other in an area corresponding to the folding axes FX1 and FX2 (refer to FIGS. 3B and 3D). The support layer SP may be provided as the first sub-support layer SP1 and the second sub-support layer SP2 spaced apart from the folding area FA, thereby improving folding characteristics of the electronic device EA.

The cushion layer CP may be disposed under the support layer SP. The cushion layer CP may prevent a pressing phenomenon and plastic deformation of the support plate MP due to an external impact and an external force. The cushion layer CP may improve impact resistance of the electronic device EA. The cushion layer CP may include an elastomer such as sponge, foam, or urethane resin. Further, the cushion layer CP may be formed to include at least one of an acryl-based polymer, a urethane-based polymer, a silicone-based polymer, and an imide-based polymer. However, this is one of the embodiments, and the disclosure is not limited thereto.

The cushion layer CP may include a first sub-cushion layer CP1 and a second sub-cushion layer CP2 spaced apart from each other in the second direction DR2. The first sub-cushion layer CP1 and the second sub-cushion layer CP2 may be spaced apart from each other in a portion corresponding to the folding axes FX1 and FX2 (refer to FIGS. 3B and 3D). The cushion layer CP may be provided as the first sub-cushion layer CP1 and the second sub-cushion layer CP2 spaced apart from the folding area FA, thereby improving folding characteristics of the electronic device EA.

The shielding layer EMP may be an electromagnetic wave shielding layer or a heat dissipating layer. Further, the shielding layer EMP may function as a joining layer.

The inter-joining layer ILP may join components of the support plate MP and the support member SPM. The inter-joining layer ILP may be provided in the form of a joining resin layer or an adhesive tape. FIG. 5 illustrates that the inter-joining layer ILP is provided as two components spaced apart from each other in the area corresponding to the folding axes FX1 and FX2 (refer to FIGS. 3B and 3D), but the disclosure is not limited thereto. Unlike the illustration, the inter-joining layer ILP may be provided as one layer that is not spaced apart in the area corresponding to the folding axes FX1 and FX2 (refer to FIGS. 3B and 3D).

The filling part SAP may be disposed outside the support layer SP and the cushion layer CP. The filling part SAP may be disposed between the support plate MP and the housing HAU (refer to FIG. 4). The filling part SAP may fill a space between the support plate MP and the housing HAU (refer to FIG. 4) and fix the support plate MP.

The lower protective film DF may be disposed between the display module DM and the support plate MP. The lower protective film DF may be a component disposed under the display module DM to protect a rear surface of the display module DM. The lower protective film DF may cover an entirety of the display module DM. The lower protective film DF may include a polymer material. In an embodiment, the lower protective film DF may be a polyimide film or a polyethylene terephthalate (“PET”) film, for example. However, this is one of the embodiments, and the lower protective film DF is not limited thereto.

The lower adhesive layer AP-D may be disposed between the support plate MP and the lower protective film DF. The support plate MP and the lower protective film DF may be coupled to each other through the lower adhesive layer AP-D. The lower adhesive layer AP-D may include a pressure sensitive adhesive (“PSA”), an optically clear adhesive film (“OCA”), or an optically clear adhesive resin layer (“OCR”). However, this is one of the embodiments, and the lower adhesive layer AP-D is not limited thereto. Unlike the illustration, the lower adhesive layer AP-D may be omitted.

The display module DM may include a display panel DP, an input sensing unit TP, and an optical layer OPL. The display panel DP may be a component that substantially generates an image. The display panel DP in an embodiment may be folded with respect to the folding axes FX1 and FX2 (refer to FIGS. 3B and 3D). Although not illustrated, the display module DM may further include an adhesive layer. The components (the display panel DP, the input sensing unit TP, the optical layer OPL, or the like) of the display module DM may be coupled through the adhesive layer.

The input sensing unit TP may be disposed on the display panel DP. The input sensing unit TP may sense an external input, convert the sensed external input into an input signal, and provide the input signal to the display panel DP. In an embodiment, the input sensing unit TP may be a touch sensing unit that senses a touch, for example. The input sensing unit TP may recognize a direct touch of the user, an indirect touch of the user, a direct touch of an object, an indirect touch of the object, or the like.

The input sensing unit TP may sense at least one of a position of a touch applied from the outside and a strength (pressure) of the touch. In an embodiment, the input sensing unit TP may have various structures or may include or consist of various materials, for example, and the disclosure is not limited to an embodiment. In an embodiment, the input sensing unit TP may sense an external input in a capacitive manner. The display panel DP may receive the input signal from the input sensing unit TP and generate an image corresponding to the input signal.

The optical layer OPL may be disposed on the input sensing unit TP. The optical layer OPL may be formed on the input sensing unit TP through a continuous process. The optical layer OPL may include a polarizing plate, a diffusion layer, or a color filter layer. In an embodiment, the optical layer OPL may include at least one of a retarder, a polarizer, a polarizing film, and a polarizing filter, for example. Unlike this, the optical layer OPL may include a plurality of color filters arranged in a predetermined arrangement. In an embodiment, the color filters may be arranged in consideration of light-emitting colors of pixels, for example. Further, the optical layer may further include a black matrix next (adjacent) to the color filters.

The protective layer PL may be disposed on the window member WM. The protective layer PL may be a functional layer that protects one surface (e.g., an upper surface) of the window member WM. In an embodiment, the protective layer PL may include PET, for example). The protective layer PL may include a fingerprint preventing coating agent, a static preventing agent, a hard coating agent, or the like.

The upper adhesive layer P-AL may be disposed between the protective layer PL and the window member WM. The protective layer PL and the window member WM may be coupled to each other through the upper adhesive layer P-AL. The upper adhesive layer P-AL may include a pressure sensitive adhesive (“PSA”), an optically clear adhesive film (“OCA”), or an optically clear adhesive resin layer (“OCR”). However, this is one of the embodiments, and the upper adhesive layer P-AL is not limited thereto.

In the specification, the fact that a first component is directly disposed/provided/formed on a second component means that a third component is not disposed/provided/formed between the first component and the second component. That is, the fact that a first component is directly disposed/provided/formed on a second component means that the first component and the second component contact each other.

The window member WM in an embodiment may be a foldable, rollable, or slidable window member. The electronic device EA including the window member WM in an embodiment may exhibit excellent reliability during folding, rolling, or sliding.

In an embodiment, the window member WM may include the synthetic resin film FL and the window adhesive layer AL disposed between the display module DM and the synthetic resin film FL. The window adhesive layer AL may include the first adhesive layer AL-1 and the second adhesive layer AL-2. The synthetic resin film FL may be disposed at an uppermost end of the window member WM. The first adhesive layer AL-1 may be directly disposed on the second adhesive layer AL-2. The synthetic resin film FL may be directly disposed on the first adhesive layer AL-1. However, a laminated structure of the window adhesive layer AL is one of the embodiments, and the laminated structure of the window adhesive layer AL may be changed depending on configurations of the first adhesive layer AL-1 and the second adhesive layer AL-2.

The synthetic resin film FL may include at least one of an acryl-based resin, an epoxy-based resin, and a siloxane-based resin. The synthetic resin film FL may be an ultra sleek cover (USC) film. The USC film may be an ultra-slim film having a thin thickness of several tens of micrometers (μm) or more and several hundreds of micrometers (μm) or less. However, this is one of the embodiments, and the synthetic resin film FL is not limited thereto.

The synthetic resin film FL may have a Young's modulus of 0.5 gigapascal (GPa) to 10 GPa at the room temperature. In an embodiment, the synthetic resin film FL may have a Young's modulus of 1 GPa to 8 GPa or 1 GPa to 5 GPa at the room temperature, for example. The synthetic resin film having a Young's modulus of less than 0.5 GPa at the room temperature is vulnerable to an external impact, and the synthetic resin film having a Young's modulus of more than 10 GPa at the room temperature is peeled off from the electronic device when a flexible operation (a folding operation, a rolling operation, and a sliding operation) is repeatedly performed. Unlike this, the synthetic resin film FL in an embodiment having a Young's modulus of 0.5 GPa to 10 GPa at the room temperature may exhibit excellent flexible operation reliability and excellent impact resistance.

The first adhesive layer AL-1 may have a Young's modulus of 0.1 megapascal (MPa) to 1 MPa at the room temperature. The first adhesive layer AL-1 having a Young's modulus of less than 0.1 MPa at the room temperature is vulnerable to an external impact, and the first adhesive layer AL-1 having a Young's modulus of more than 1 MPa at the room temperature is peeled from the electronic device when the flexible operation is repeatedly performed. Unlike this, the first adhesive layer AL-1 in an embodiment having a Young's modulus of 0.1 MPa to 1 MPa at the room temperature may exhibit excellent flexible operation reliability and excellent impact resistance.

A crosslinking degree of the first adhesive layer AL-1 may be greater than or equal to 90%. The first adhesive layer having a crosslinking degree smaller than 90% is vulnerable to an external impact, and optical transparency thereof is reduced due to an uneven refractive index. Unlike this, the first adhesive layer AL-1 having a crosslinking degree greater than or equal to 90% may exhibit excellent impact resistance and excellent display quality.

The second adhesive layer AL-2 may have a Young's modulus of 0.01 MPa to 0.1 MPa at the room temperature. In an embodiment, the second adhesive layer AL-2 may have a Young's modulus of 0.05 MPa to 0.1 MPa at the room temperature, for example. The Young's modulus of the second adhesive layer AL-2 may be smaller than the Young's modulus of the first adhesive layer AL-1. The second adhesive layer AL-2 having a Young's modulus lower than that of the first adhesive layer AL-1 may easily and repeatedly perform a flexible operation.

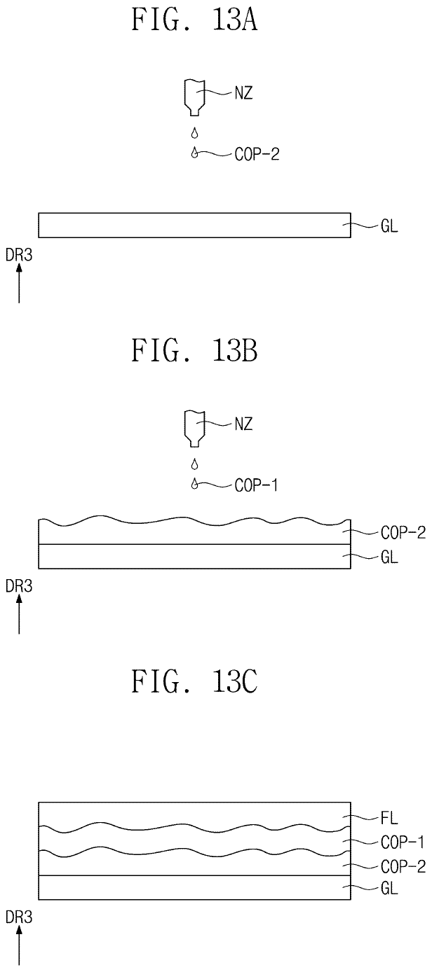

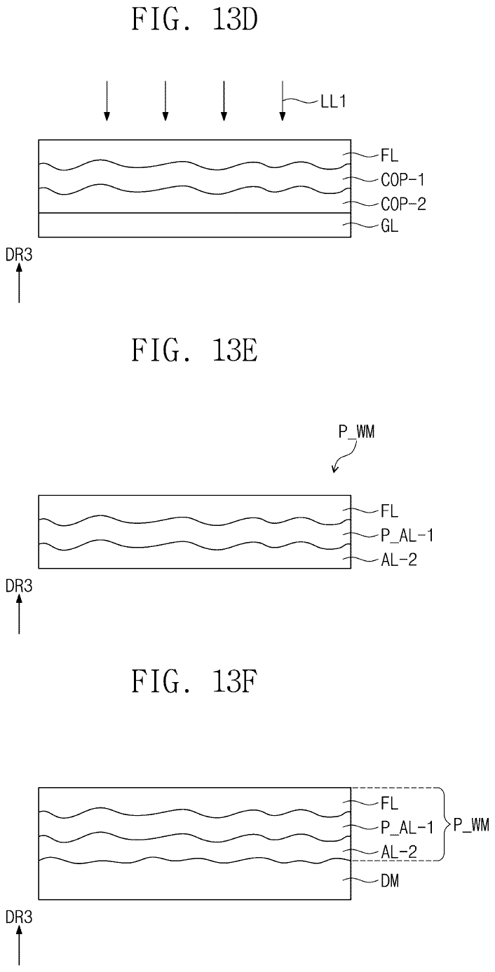

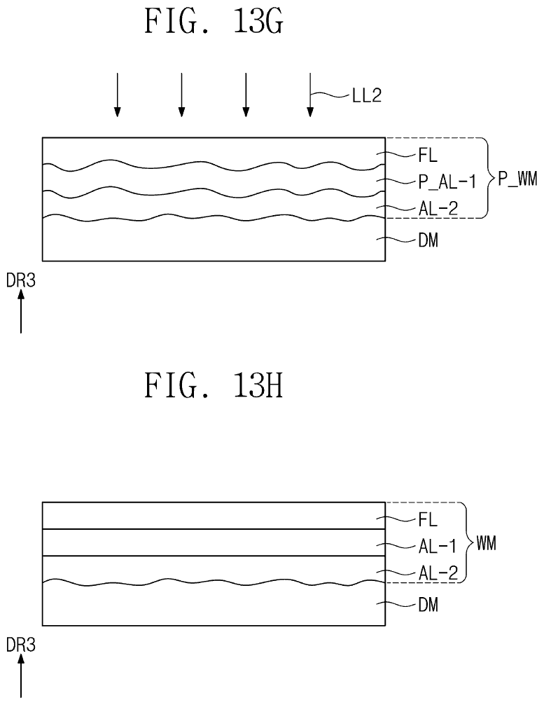

The first adhesive layer AL-1 may include a post-curable adhesive COP-1 (refer to FIG. 13B). The post-curable adhesive COP-1 (refer to FIG. 13B) may be an adhesive that is cured after being introduced onto the display module DM. The second adhesive layer AL-2 may include a low hardness adhesive COP-2 (refer to FIG. 13A) having a hardness smaller than that of the post-curable adhesive COP-1 (refer to FIG. 13B). As the low hardness adhesive COP-2 (refer to FIG. 13A) has a low hardness, a stable adhesive force may be maintained even in the repeated flexible operation of the electronic device EA.

Each of the post-curable adhesive COP-1 (refer to FIG. 13B) and the low hardness adhesive COP-2 (refer to FIG. 13A) may include a pressure sensitive adhesive (“PSA”), an optically clear adhesive film (“OCA”), or an optically clear adhesive resin layer (“OCR”). However, this is one of the embodiments, and the type of adhesive is not limited thereto.

The window adhesive layer AL may uniformly coat a non-uniform gap formed between the synthetic resin film FL and the display module DM. Accordingly, in the electronic device EA including the window adhesive layer AL, reflection of light may become constant and an adhesive force between the synthetic resin film FL and the display module DM may be improved. Thus, the electronic device EA in an embodiment may exhibit improved display quality and excellent reliability.

In an embodiment, a thickness of the window member WM may be in a range of 25 μm to 100 μm. In an embodiment, the thickness of the window member WM may be in a range of 25 μm to 50 μm, for example. The window member having a thickness smaller than 25 μm is vulnerable to an external impact, distortion occurs in an image, and a flexible operation of the window member having a thickness greater than 100 μm is not easy. Unlike this, a flexible operation of the window member WM having a thickness of 25 μm to 100 μm may be easy, and the window member WM may exhibit excellent impact resistance and excellent reliability.

The electronic device EA in an embodiment may have surface quality of 0.3 or less. The electronic device having surface quality greater than 0.3 has a rough surface, and an image reflected from the surface is distorted. Unlike this, the electronic device EA having surface quality smaller than or equal to 0.3 in an embodiment has a smooth surface, has relatively high reflection quality, and thus exhibits excellent display quality.

Table 1 below represents surface quality of the electronic device according to Embodiment and Comparative Example. The surface quality is obtained by measuring surface quality of the electronic device using an Optimap PSD device. A phase measuring deflectometry which measures a curve and a defect of the surface by projecting a periodic pattern onto the surface and measuring a phase change of the reflected pattern is used. The measured surface quality is a diopter value, which represents a curvature of the surface. A relatively high diopter value indicates that the curvature of the surface is high, which means that roughness or defects of the surface are prominent.

In Table 1, Embodiment corresponds to an electronic device in which a synthetic resin film, a first adhesive layer disposed under the synthetic resin film, and a second adhesive layer disposed under the first adhesive layer are integrally provided as the window member and are joined on the display module. In Embodiment, the synthetic resin film is a USC film including an epoxy resin, and the post-curable adhesive used for the first adhesive layer and the low hardness adhesive used for the second adhesive layer are acryl-based adhesives. Comparative Example corresponds to an electronic device in which the window member including ultra thin glass (“UTG”) and an adhesive layer disposed under the UTG is joined onto the display module. In Comparative Example, the adhesive layer includes or consists of a pressure-sensitive adhesive.

TABLE 1

| | | Surface quality | |
|---|---|---|---|
| | | Primary | Secondary |
| Classification | Window member | measurement | measurement |
| Embodiment | First adhesive layer | 0.20 | 0.22 |
| | is disposed under USC. | | |
| | Second adhesive layer | | |
| | is disposed under first | | |
| | adhesive layer | | |
| Comparative | Adhesive layer is | 0.38 | — |
| Example | disposed under UTG | | |

Referring to Table 1, the electronic device according to Comparative Example has surface quality greater than 0.3. The electronic device according to Comparative Example has surface quality greater than 0.3, and thus secondary measuring is not performed. In the electronic device according to Comparative Example, the window member does not include a post-curable adhesive and a relatively low hardness adhesive. Accordingly, in the electronic device according to Comparative Example, surface curve of the display module is not resolved, and when light is radiated, a lot of diffraction occurs due to the surface curve. Thus, the electronic device according to Comparative Example exhibits relatively high surface quality.

Unlike this, the electronic device according to Embodiment has surface quality smaller than or equal to 0.3. In the electronic device according to Embodiment, the window member including the post-curable adhesive and the low hardness adhesive is introduced onto the display module, the surface curve of the display module is filled, and the synthetic resin film uniformly adheres onto the display module. Accordingly, when light is radiated, a surface is smooth, resulting in less diffraction. Thus, it may be seen that the electronic device according to Embodiment exhibits relatively low surface quality and excellent display quality. Further, the electronic device according to Embodiment has surface quality smaller than or equal to 0.3 even during the secondary surface quality measurement after the primary surface quality measurement. The secondary surface quality measurement is performed by repeating the same test under the same condition as the primary surface quality measurement, and therefore, it may be seen that the surface quality of the electronic device according to Embodiment is a value having reliability.

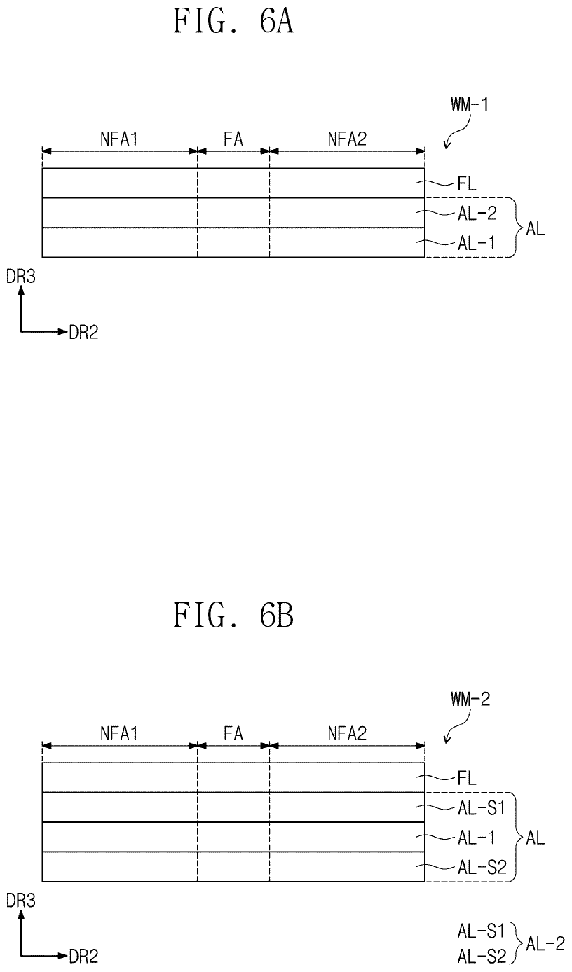

FIGS. 6A and 6B are cross-sectional views illustrating a window member according to the disclosure. Hereinafter, in description of FIGS. 6A and 6B, contents duplicated with the contents described with reference to FIGS. 1 to 5 will not be described again, and differences therebetween will be mainly described.

A window member WM-1 illustrated in FIG. 6A differs from the window member WM illustrated in FIG. 5 in terms of a laminated order of the first adhesive layer AL-1 and the second adhesive layer AL-2. The second adhesive layer AL-2 may be directly disposed on the first adhesive layer AL-1. The synthetic resin film FL may be directly disposed on the second adhesive layer AL-2.

A window member WM-2 illustrated in FIG. 6B differs from the window member WM illustrated in FIG. 5 in terms of the number of second adhesive layers AL-2. The second adhesive layer AL-2 may be provided as a plurality of second adhesive layers AL-2. The second adhesive layer AL-2 may include a first sub-adhesive layer AL-S1 and a second sub-adhesive layer AL-S2. The synthetic resin film FL may be disposed on the first sub-adhesive layer AL-S1, the first sub-adhesive layer AL-S1 may be disposed on the first adhesive layer AL-1, and the first adhesive layer AL-1 may be disposed on the second sub-adhesive layer AL-S2. The first adhesive layer AL-1 may be disposed between the first sub-adhesive layer AL-S1 and the second sub-adhesive layer AL-S2.

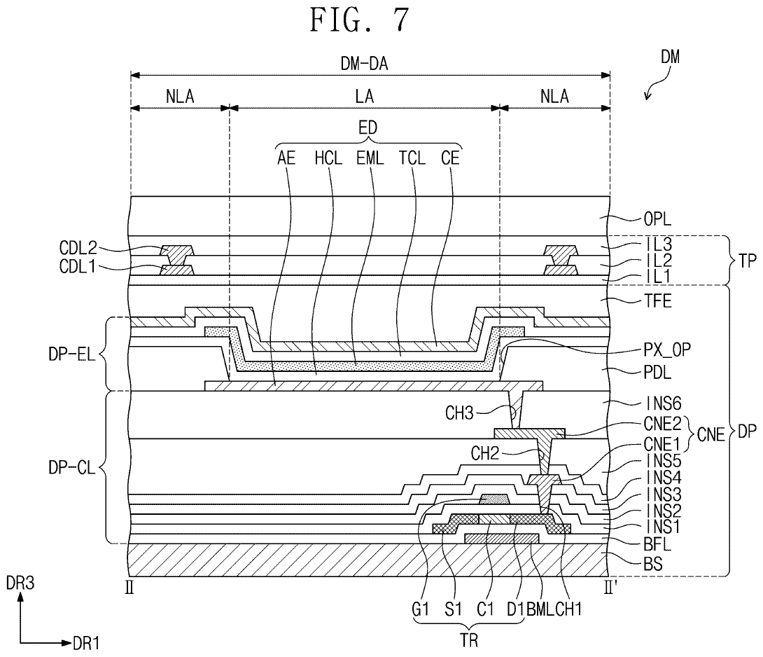

FIG. 7 is a cross-sectional view illustrating a portion corresponding to line II-II′ of FIG. 4. FIG. 7 may be a cross-sectional view illustrating the display area DM-DA of the display module DM. A configuration of the display module DM illustrated in FIG. 7 is one of the embodiments, and the disclosure is not limited thereto.

A base substrate BS may include a single layer or multiple layers. In an embodiment, the base substrate BS may include a first synthetic resin layer, a multi-layered or single-layered inorganic layer, and a second synthetic resin layer disposed on the multi-layered or single-layered inorganic layer, for example. Each of the first synthetic resin layer and the second synthetic resin layer may include a polyimide-based resin. Further, each of the first synthetic resin layer and the second synthetic resin layer may include at least one of an acryl-based resin, a methacryl-based resin, a polyisoprene-based resin, a vinyl-based resin, an epoxy-based resin, a urethane-based resin, a cellulose-based resin, a siloxane-based resin, a polyamide-based resin, and a perylene-based resin. In the specification, a “X-based” resin means a resin including a functional group of “X” where X is a chemical component.

The display panel DP may include a transistor TR and a light-emitting element ED. The transistor TR and the light-emitting element ED may be disposed on the base substrate BS. Although FIG. 7 illustrates the one transistor TR, the display panel DP may include a plurality of transistors and at least one capacitor for substantially driving the light-emitting element ED.

A circuit layer DP-CL may be disposed on the base substrate BS. The circuit layer DP-CL may include a shielding electrode BML, the transistor TR, a connection electrode CNE, and a plurality of insulating layers BFL and INS1 to INS6. The plurality of insulating layers BFL and INS1 to INS6 may include the buffer layer BFL and the first to sixth insulating layers INS1 to INS6. However, a laminated structure of the circuit layer DP-CL illustrated in FIG. 7 is one of the embodiments, and the laminated structure of the circuit layer DP-CL may be changed according to a configuration of the display panel DP and a process of the circuit layer DP-CL or the like.

The shielding electrode BML may be disposed on the base substrate BS. The shielding electrode BML may overlap the transistor TR. The shielding electrode BML may block light incident on the transistor TR from a lower portion of the display panel DP to protect the transistor TR. The shielding electrode BML may include a conducive material. When a voltage is applied to the shielding electrode BML, a threshold voltage of the transistor TR disposed on the shielding electrode BML may be maintained. However, the disclosure is not limited thereto, and the shielding electrode BML may be a floating electrode. The shielding electrode BML may be omitted.

The buffer layer BFL may be disposed on the base substrate BS to cover the shielding electrode BML. The buffer layer BFL may include an inorganic layer. The buffer layer BFL may improve a coupling force between a semiconductor pattern or a conductive pattern disposed on the buffer layer BFL and the base substrate BS.

The transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicon, amorphous silicon, or a metal oxide, a material may be applied without limitation as long as the material has semiconductor properties, and the disclosure is not limited thereto.

The semiconductor pattern may include a plurality of areas divided according to a magnitude of conductivity. An area of the semiconductor pattern, which is doped with a dopant or reduced with a metal oxide may have relatively high conductivity and may substantially serve as a source electrode or a drain electrode of the transistor TR. An area of the semiconductor pattern having relatively high conductivity may correspond to the source S1 and the drain D1 of the transistor TR. An area of the semiconductor pattern, which is not doped or doped at a relatively low concentration or has relatively low conductivity due to non-reduction of a metal oxide, may correspond to the channel C1 (or an active area) of the transistor TR.

The first insulating layer INS1 may cover the semiconductor pattern of the transistor TR and may be disposed on the buffer layer BFL. The gate G1 of the transistor TR may be disposed on the first insulating layer INS1. On a plane, the gate G1 may overlap the channel C1 of the transistor TR. The gate G1 may function as a mask in a process of doping the semiconductor pattern of the transistor TR.

The second insulating layer INS2 may cover the gate G1 and may be disposed on the first insulating layer INS1. The third insulating layer INS3 may be disposed on the second insulating layer INS2.

The connection electrode CNE may include a first connection electrode CNE1 and a second connection electrode CNE2 for electrically connecting the transistor TR and the light-emitting element ED. However, a configuration of the connection electrode CNE that electrically connects the transistor TR and the light-emitting element ED is not limited thereto, one of the first connection electrode CNE1 and the second connection electrode CNE2 may be omitted or an additional connection electrode may be further included.

The first connection electrode CNE1 may be disposed on the third insulating layer INS3. The first connection electrode CNE1 may be connected to the drain D1 through a first contact hole CH1 passing through the first insulating layer INS1, the second insulating layer INS2, and the third insulating layer INS3. The fourth insulating layer INS4 may cover the first connection electrode CNE1 and may be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 passing through by the fourth insulating layer INS4 and the fifth insulating layer INS5. The sixth insulating layer INS6 may cover the second connection electrode CNE2 and may be disposed on the fifth insulating layer INS5.

Each of the first to sixth insulating layers INS1 to INS6 may include an inorganic layer or an organic layer. In an embodiment, the inorganic layer may include at least one of an aluminum oxide, a titanium oxide, a silicon oxide, a silicon oxy nitride, a zirconium oxide, and a hafnium oxide, for example. The organic layer may also include at least one of an acrylic resin, a methacrylic resin, a polyisoprene resin, a vinyl resin, an epoxy resin, a urethane resin, a cellulose resin, a siloxane resin, a polyamide resin, and a perylene resin.

A display element layer DP-EL may include a pixel defining film PDL and the light-emitting element ED. The light-emitting element ED may include a first electrode AE, a hole control layer HCL, a light-emitting layer EML, an electron control layer TCL, and a second electrode CE. The second electrode CE may be disposed on the first electrode AE. The light-emitting layer EML may be disposed between the first electrode AE and the second electrode CE. The hole control layer HCL may be disposed between the first electrode AE and the light-emitting layer EML. The electron control layer TCL may be disposed between the light-emitting layer EML and the second electrode CE.

The first electrode AE may be disposed on the sixth insulating layer INS6. The first electrode AE may be connected to the second connection electrode CNE2 through a third contact hole CH3 passing through the sixth insulating layer INS6. The first electrode AE may be electrically connected to the drain D1 of the transistor TR through the first connection electrode CNE1 and the second connection electrode CNE2.

The first electrode AE may include or consist of a metal material, a metal alloy, or a conductive compound. The first electrode AE may be an anode or a cathode. However, the disclosure is not limited thereto. Further, the first electrode AE may be a pixel electrode. The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a combination of two or more selected therefrom, or an oxide thereof.

When the first electrode AE is the transmissive electrode, the first electrode AE may include a transparent metal oxide, e.g., an indium tin oxide (“ITO”), an indium zinc oxide (“IZO”), a zinc oxide (ZnO), an indium tin zinc oxide (“ITZO”) or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or combination thereof (e.g., a combination of Ag and Mg). In an alternative embodiment, the first electrode AE may include a multi-layer structure including a reflective film or a semi-transmissive film including or consisting of the above materials and a transparent conductive film including or consisting of an ITO, an IZO, a zinc oxide (ZnO), an ITZO, or the like. In an embodiment, the first electrode AE may have a three-layer structure of ITO/Ag/ITO, for example, but the disclosure is not limited thereto. Further, the disclosure is not limited thereto, and the first electrode AE may include the above-described metal materials, combinations of two or more types of metal materials selected from the above-described metal materials, oxides of the above-described metal materials, or the like.

The pixel defining film PDL may be disposed on the sixth insulating layer INS6. A light-emitting opening PX_OP, through which a portion of the first electrode AE is exposed, may be defined in the pixel defining film PDL. A portion of the first electrode AE exposed by the light-emitting opening PX_OP may be defined as a light-emitting area LA.

The display area DM-DA of the display module DM may include the light-emitting area LA and a light-shielding area NLA. An area in which the pixel defining film PDL is disposed may correspond to the light-shielding area NLA. The light-shielding area NLA may surround the light-emitting area LA inside the display area DM-DA.

The hole control layer HCL may be disposed on the first electrode AE and the pixel defining film PDL. The hole control layer HCL may be provided as a common layer overlapping the light-emitting area LA and the light-shielding area NLA. Unlike the illustration, the hole control layer HCL may be disposed in an area corresponding to the light-emitting opening PX_OP. The hole control layer HCL may include at least one of a hole transport layer, a hole injection layer, and an electron blocking layer. The hole control layer HCL may include a known hole injection material and/or a known hole transport material.

The light-emitting layer EML may be disposed on the hole control layer HCL. The light-emitting layer EML may be disposed in an area corresponding to the light-emitting opening PX_OP. Unlike this, the light-emitting layer EML may be provided as a common layer. The light-emitting layer EML may include an organic light-emitting material and/or an inorganic light-emitting material. The light-emitting layer EML may emit light having any one color among red, green, and blue. In an embodiment, the light-emitting layer EML may emit blue light, for example.

The electron control layer TCL may be disposed on the light-emitting layer EML. The electron control layer TCL may be provided as a common layer overlapping the light-emitting area LA and the light-shielding area NLA. Unlike the illustration, the electron control layer TCL may be disposed in an area corresponding to the light-emitting opening PX_OP. The electron control layer TCL may include at least one of an electron transport layer, an electron injection layer, and a hole blocking layer. The electron control layer TCL may include a known electron injection material and/or a known electron transport material.

The second electrode CE may be disposed on the electron control layer TCL. The second electrode CE may be provided as a common layer overlapping the light-emitting area LA and the light-shielding area NLA. The second electrode CE may be a common electrode. The second electrode CE may be a cathode or an anode, but the disclosure is not limited thereto. In an embodiment, when the first electrode AE is an anode, the second electrode CE may be a cathode, or when the first electrode AE is a cathode, the second electrode CE may be an anode, for example.

The second electrode CE may be a transmissive electrode, a semi-transmissive electrode, or a reflective electrode. When the second electrode CE is a transmissive electrode, the second electrode CE may include or consist of a transparent metal oxide, e.g., an ITO, IZO, a zinc oxide (ZnO), an ITZO, or the like.

When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or combination (e.g., AgMg, AgYb, or MgYb) including the same. In an alternative embodiment, the second electrode CE may have a multi-layer structure including a reflective film or a semi-transmissive film including or consisting of the above material and a transparent conductive film including or consisting of an ITO, an IZO, a zinc oxide (ZnO), and an ITZO. In an embodiment, the second electrode CE may include the above-described metal materials, a combination of two or more metal materials selected from the above-described metal materials, an oxide of the above-described metal materials, or the like, for example.

An encapsulation layer TFE may be disposed on the second electrode CE and cover the light-emitting element ED. The encapsulation layer TFE may include a plurality of thin films. In an embodiment, the encapsulation layer TFE may include inorganic films arranged on the second electrode CE and an organic film disposed between the inorganic films, for example. The inorganic film may protect the light-emitting element ED from moisture/oxygen, and the organic film may protect the light-emitting element ED from foreign substances such as dust particles.

The input sensing unit TP may include a first sensing insulating layer IL1, a second sensing insulating layer IL2, and a third sensing insulating layer IL3. The input sensing unit TP may include at least one conductive layer disposed on the sensing insulating layers. The input sensing unit TP may include a first conductive layer CDL1 and a second conductive layer CDL2.

The first sensing insulating layer IL1 may be disposed on the encapsulation layer TFE. The first sensing insulating layer IL1 may include at least one inorganic insulating layer. The first sensing insulating layer IL1 may contact the encapsulation layer TFE. Unlike this, the first sensing insulating layer IL1 may be omitted, and in this case, the first conductive layer CDL1 may contact the encapsulation layer TFE.

The first conductive layer CDL1 may be disposed on the first sensing insulating layer IL1. The first conductive layer CDL1 may include a plurality of first conductive patterns. The plurality of first conductive patterns may be arranged on the first sensing insulating layer IL1. The second sensing insulating layer IL2 may be disposed on the first sensing insulating layer IL1 to cover at least a portion of the first conductive layer CDL1.

The second conductive layer CDL2 may be disposed on the second sensing insulating layer IL2. The second conductive layer CDL2 may include a plurality of second conductive patterns. The plurality of second conductive patterns may be arranged on the second sensing insulating layer IL2. The plurality of second conductive patterns may be connected to the plurality of first conductive patterns through a contact hole defined in the second sensing insulating layer IL2, respectively.

Each of the plurality of first conductive patterns of the first conductive layer CDL1 and the plurality of second conductive patterns of the second conductive layer CDL2 may be disposed to correspond to the light-shielding area NLA. Each of the plurality of first conductive patterns of the first conductive layer CDL1 and the plurality of second conductive patterns of the second conductive layer CDL2 may correspond to a mesh pattern.

The third sensing insulating layer IL3 may be disposed on the second sensing insulating layer IL2 and cover the second conductive layer CDL2. Each of the second sensing insulating layer IL2 and the third sensing insulating layer IL3 may include an inorganic insulating layer or an organic insulating layer.

Each of the first conductive layer CDL1 and the second conductive layer CDL2 may have a single-layer structure or have a multi-layer structure in which layers are laminated in the third direction axis (also referred to as a third direction) DR3. The conductive layers CDL1 and CDL2 having a single-layer structure may include a metal layer or a transparent conductive layer. The metal layer may include molybdenum, silver, titanium, copper, aluminum, or alloys thereof. The transparent conductive layer may include a transparent conductive oxide such as an ITO, an IZO, a zinc oxide (ZnO), and an IZTO. Further, the transparent conductive layer may include a conductive polymer such as poly(3,4-ethylenedioxythiophene) (“PEDOT”), metal nanowires, graphene, or the like.

The conductive layers CDL1 and CDL2 having a multi-layer structure may include metal layers. The metal layers may have, e.g., a three-layer structure of titanium (Ti)/aluminum (Al)/titanium (Ti). The conductive layers CDL1 and CDL2 having a multi-layer structure may include at least one metal layer and at least one transparent conductive layer.

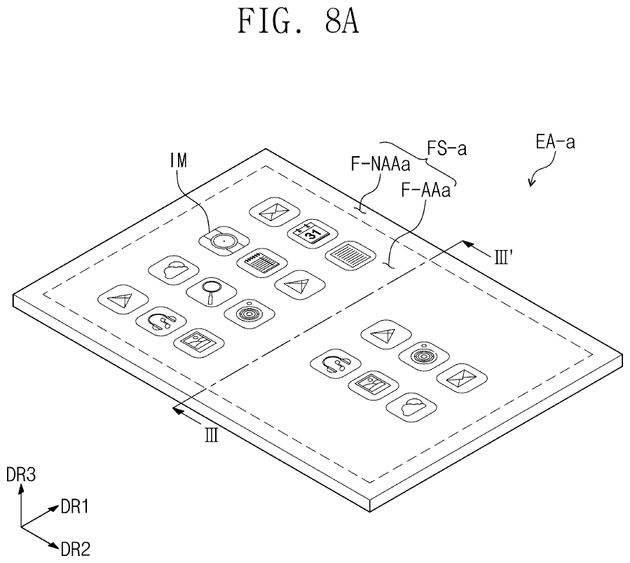

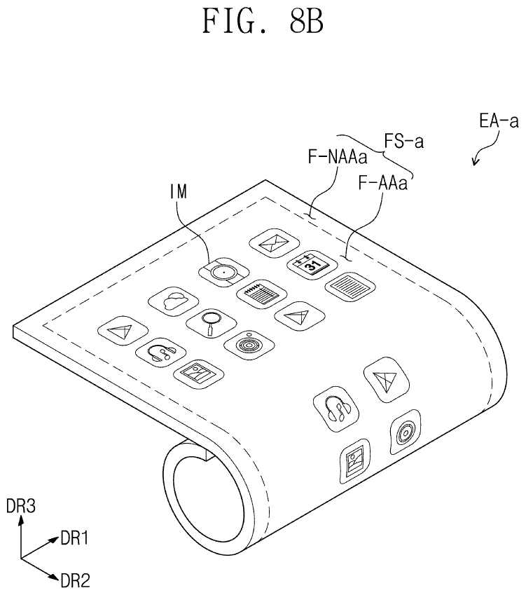

FIG. 8A is a perspective view illustrating an electronic device EA-a according to the disclosure. FIG. 8B is a perspective view illustrating a process of rolling the electronic device EA-a illustrated in FIG. 8A. The electronic device EA-a of FIGS. 8A and 8B illustrates a portable electronic device capable of a rolling operation.

Referring to FIG. 8A, the electronic device EA-a may have a quadrangular shape, e.g., rectangular shape including long sides parallel to the first direction DR1 and short sides parallel to the second direction DR2. However, this is one of the embodiments, and a shape of the electronic device EA-a is not limited thereto.

FIG. 8B is a perspective view illustrating a state in which the electronic device EA-a illustrated in FIG. 8A is wound. Referring to FIG. 8B, the electronic device EA-a may be a flexible electronic device. The electronic device EA-a may be rolled up like a scroll. The electronic device EA-a may be rolled up in the second direction DR2. The electronic device EA-a may be rolled up from one side of the electronic device EA-a. The electronic device EA-a may be rolled up so that a display surface FS-a faces the outside. Further, the electronic device EA-a may be rolled up so that the display surface FS-a faces the inside. In an embodiment, the display surface FS-a may include an active area F-AAa and a peripheral area F-NAAa surrounding the active area F-AAa.

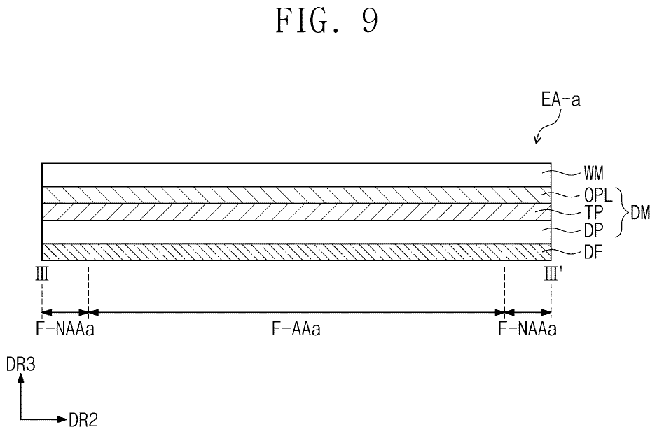

FIG. 9 is a cross-sectional view illustrating a portion corresponding to line III-III′ illustrated in FIG. 8A. FIG. 9 may be a cross-sectional view illustrating the electronic device EA-a. Hereinafter, in description of FIG. 9, contents duplicated with the contents described with reference to FIGS. 1 to 8B will not be described again, and differences therebetween will be mainly described.

Referring to FIG. 9, the electronic device EA-a may include the display module DM, the window member WM, and the lower protective film DF. The display module DM may include the display panel DP, the input sensing unit TP, and the optical layer OPL.

The display module DM and the window member WM may be rolled. The display module DM and the window member WM may be rolled or unfolded in the second direction DR2.

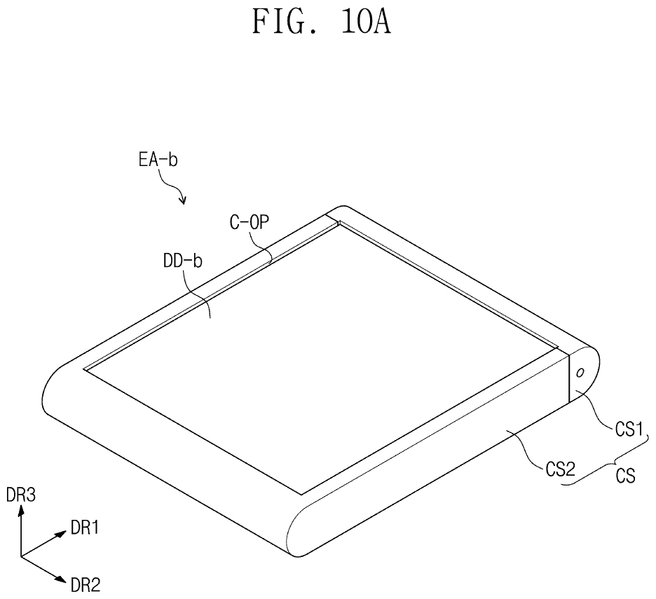

FIG. 10A is a perspective view illustrating an electronic device EA-b according to the disclosure. FIG. 10A illustrates, as one of the embodiments, that the electronic device EA-b is a portable electronic device capable of a sliding operation. FIG. 10B is a perspective view illustrating a process of sliding the electronic device EA-b illustrated in FIG. 10A. FIG. 10A illustrates the electronic device EA-b in a first mode, and FIG. 10B illustrates the electronic device EA-b in a second mode.

Referring to FIGS. 10A and 10B, the electronic device EA-b may include a display device DD-b and a case CS in which the display device DD-b is accommodated. At least a portion of the display device DD-b may be exposed to the outside through a display opening C-OP defined in an upper portion of the case CS.

The case CS may include a first case CS1 and a second case CS2. The first case CS1 and the second case CS2 may be coupled to each other to accommodate the display device DD-b. The first case CS1 may be coupled to the second case CS2 so as to move in a direction parallel to the first direction axis DR1. The first case CS1 may be coupled to the second case CS2 to move closer to or away from the second case CS2.

A display surface of the display device DD-b exposed by the display opening C-OP may be parallel to the plane defined by the first direction axis DR1 and the second direction axis DR2 intersecting the first direction axis DR1. The display device DD-b may display an image in a direction parallel to the third direction axis DR3 on a display surface parallel to the plane defined by the first direction axis DR1 and the second direction axis DR2.

Referring to FIGS. 10A and 10B, an area of the display surface of the display device DD-b exposed through the display opening C-OP of the case CS may be adjusted according to movement of the first case CS1. As the first case CS1 moves, an opening area of the display opening C-OP may increase in the first direction DR1.

The display device DD-b may be a flexible display module and may be supported by a support layer disposed under the display device DD-b. When the first case CS1 moves in the first direction DR1, the support layer connected to the first case CS1 may move in the first direction DR1 together. Accordingly, the display device DD-b disposed on the support layer may also move in the first direction DR1 according to the movement of the first case CS1. As an end of the display device DD-b moves in the first direction DR1 together with the first case CS1, a portion of the display device DD-b accommodated in the second case CS2 in the first mode may be exposed to the outside, and the display surface of the display device DD-b exposed through the display opening C-OP may be expanded.

FIG. 10A illustrates the electronic device EA-b in the first mode in which the first case CS1 is disposed closest to the second case CS2 in the first direction DR1 in an operation state of the electronic device EA-b. In the first mode, a portion extending from one area of the display device DD-b exposed by the display opening C-OP may be folded at a predetermined curvature and accommodated in the second case CS2. The first mode in which the display surface of the display device DD-b is set to a basic size may be defined as a basic mode.

FIG. 10B illustrates the electronic device EA-b in the second mode in which the first case CS1 is disposed farthest from the second case CS2 in the first direction DR1 in the operation state of the electronic device EA-b. In the electronic device EA-b in the second mode, the area of the display surface of the display device DD-b exposed by the display opening C-OP may be expanded compared to the first mode. That is, the second mode in which the display surface is expanded in the basic mode may be defined as an expansion mode.

The first mode and the second mode of the electronic device EA-b may be determined according to sliding operations of the case CS and the display device DD-b. As the user operates the electronic device EA-b from the first mode to the second mode, the display surface of the electronic device EA-b may be expanded, and an image may be visually recognized through the expanded display surface. Further, as the user operates the electronic device EA-b from the second mode to the first mode, the display surface of the electronic device EA-b may be reduced, and an image may be visually recognized through the reduced display surface. That is, as the user selects and operates the electronic device EA-b in either the first mode or the second mode, an area of the display surface of the electronic device EA-b exposed from the case CS may be variously adjusted.

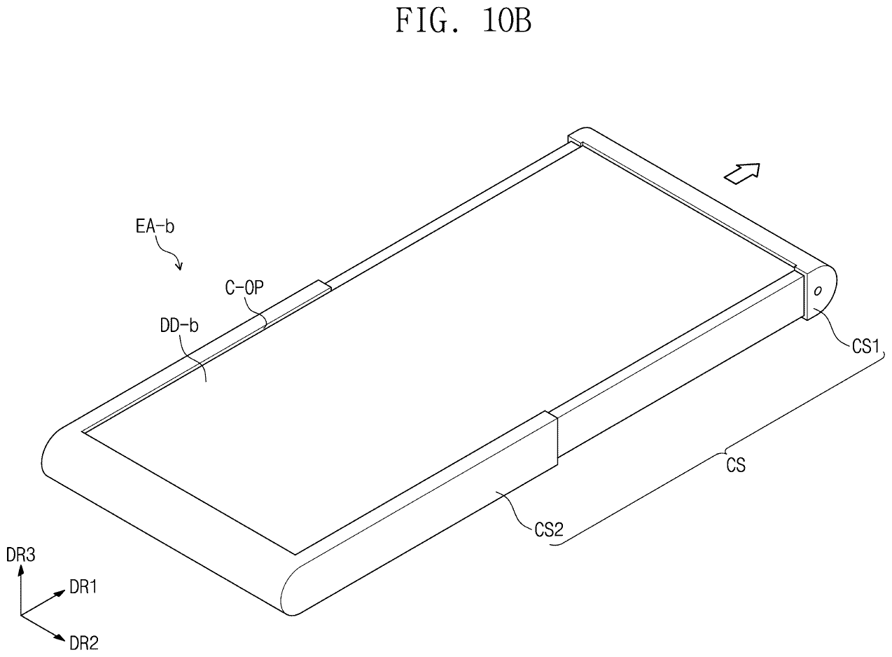

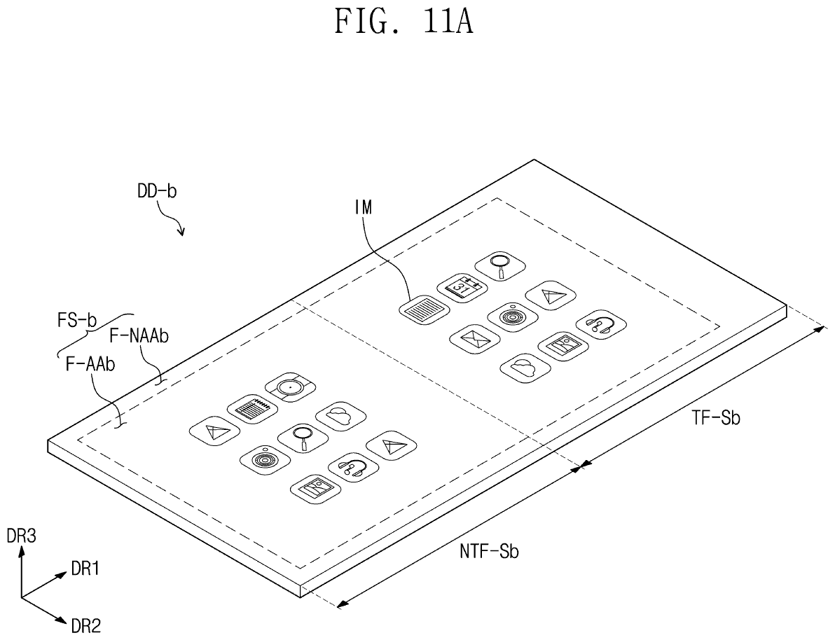

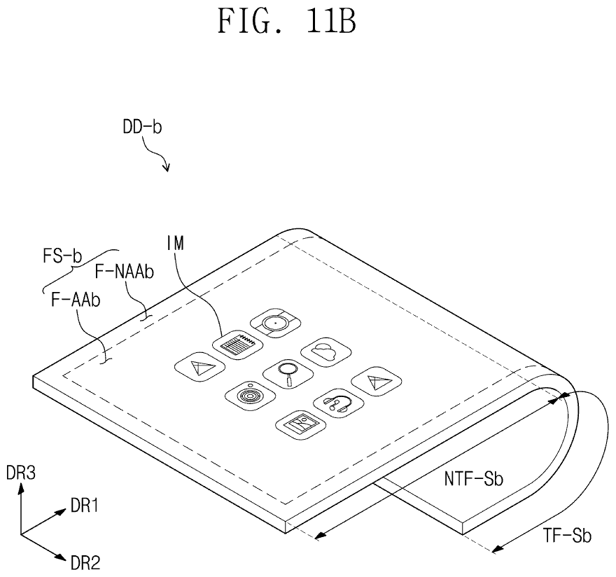

FIG. 11A is a perspective view of the display device DD-b accommodated in the case CS illustrated in FIG. 10A. The display device DD-b may include a deformation part TF-Sb and a non-deformation part NTF-Sb next (adjacent) to the deformation part TF-Sb. The deformation part TF-Sb may be a part capable of a sliding operation. The deformation part TF-Sb may be a portion accommodated in the first case CS1 in the first mode. In the first mode, the non-deformation part NTF-Sb may correspond to the display surface exposed through the display opening C-OP. In the first mode, the display surface corresponding to the deformation part TF-Sb may not be exposed through the display opening C-OP. In the second mode, at least a portion of the deformation part TF-Sb may correspond to the display surface exposed through the display opening C-OP. In an embodiment, the display device DD-b may include a display surface FS-b which includes an active area F-AAb and a peripheral area F-NAAb surrounding the active area F-AAb.

FIG. 11B is a perspective view illustrating a state in which the display device DD-b illustrated in FIG. 11A is wound. FIG. 11B is a view illustrating the display device DD-b in the above-described first mode. In the first mode, the deformation part TF-Sb may be accommodated in the first case CS1 (refer to FIG. 10A) in a wound state. As the first case CS1 moves in the first direction DR1, at least a part of the deformation part TF-Sb may be exposed by the display opening C-OP in the second mode.

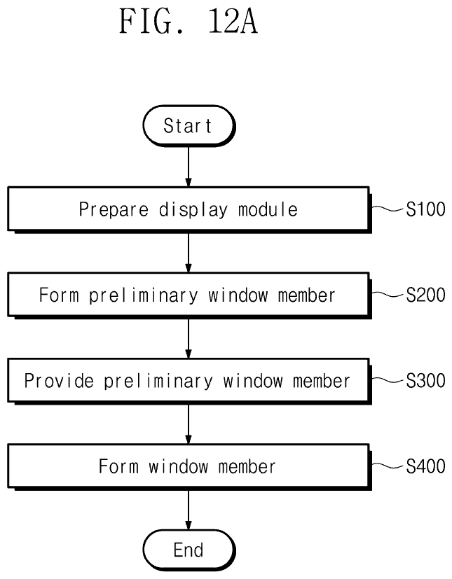

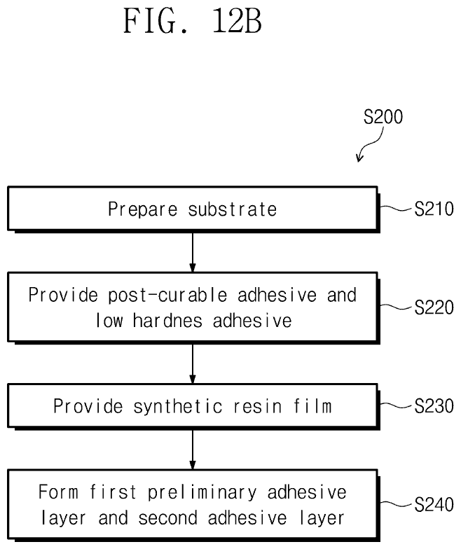

The electronic device in an embodiment may be manufactured by the method of manufacturing an electronic device. FIGS. 12A and 12B are flowcharts illustrating a method of manufacturing an electronic device. FIGS. 13A to 13H are schematic views illustrating operations of manufacturing an electronic device. Hereinafter, in description of FIGS. 12A to 13H, contents duplicated with the contents described with reference to FIGS. 1 to 11B will not be described again, and differences will be mainly described.

Referring to FIG. 12A, the method of manufacturing an electronic device in an embodiment may include operation S100 of preparing a display module including a deformation part capable of folding, rolling, or sliding and a non-deformation part next (adjacent) to the deformation part, operation S200 of forming a preliminary window member including a synthetic resin film, a first preliminary adhesive layer, and a second adhesive layer, operation S300 of providing the preliminary window member on the display module, and operation S400 of forming a window member including the synthetic resin film, a first adhesive layer, and a second adhesive layer. Referring to FIG. 12B, operation S200 of forming the preliminary window member may include operation S210 of preparing a substrate, operation S220 of providing a post-curable adhesive and a low hardness adhesive having a lower hardness than that of the post-curable adhesive, operation S230 of providing the synthetic resin film onto the adhesives, and operation S240 of forming a first preliminary adhesive layer and a second adhesive layer.

FIGS. 13A to 13H may be a method of manufacturing an electronic device including the window member WM illustrated in FIG. 5. However, this is one of the embodiments, and a manufacturing order or the like may be changed according to the configurations of the window members WM-1 and WM-2 (refer to FIGS. 6A and 6B), and the method of manufacturing an electronic device is not limited to an embodiment.

Referring to FIG. 13A, the low hardness adhesive COP-2 may be provided on a substrate GL. The low hardness adhesive COP-2 may have a hardness lower than that of the post-curable adhesive COP-1. The substrate GL may be a glass substrate, but the type of the substrate is not limited thereto. The substrate GL is a temporary substrate used for manufacturing a preliminary window member P_WM (refer to FIG. 13E) and may be removed after the manufacturing. Referring to FIG. 13B, the post-curable adhesive COP-1 may be directly provided on the low hardness adhesive COP-2.

In FIGS. 13A and 13B, the post-curable adhesive COP-1 and the low hardness adhesive COP-2 may be acryl-based adhesives. Further, each of the post-curable adhesive COP-1 and the low hardness adhesive COP-2 may be provided by an inkjet printing method or a dispensing method. The post-curable adhesive COP-1 and the low hardness adhesive COP-2 may be provided through a nozzle NZ. However, this is one of the embodiments, and the adhesives COP-1 and COP-2 may be adhesives including a functional group other than the acryl-based adhesive. Further, a method and a device for providing the post-curable adhesive COP-1 and the low hardness adhesive COP-2 are not limited thereto.

Referring to FIG. 13C, the synthetic resin film FL may be directly provided on the post-curable adhesive COP-1. Referring to FIGS. 13D and 13E, first light LL1 may be provided to the synthetic resin film FL, the post-curable adhesive COP-1, and the low hardness adhesive COP-2 to form the preliminary window member P_WM. The post-curable adhesive COP-1 may be cured by the first light LL1 to form a preliminary first adhesive layer P_AL-1, and the low hardness adhesive COP-2 may be cured to form a second adhesive layer AL-2. The preliminary first adhesive layer P_AL-1 formed by the first light LL1 may be in a semi-cured state. The preliminary first adhesive layer P_AL-1 of FIG. 13E may be illustrated in a viscoelastic shape in a semi-cured state.

Referring to FIG. 13F, the preliminary window member P_WM may be provided on the display module DM. The display module DM illustrated in FIGS. 13F to 13H may illustrate a surface curve of the display module DM illustrated in FIG. 5. When the preliminary window member P_WM is provided on the display module DM, the preliminary first adhesive layer P_AL-1 may be in a semi-cured state and in a state that is well spread and viscoelastic on a surface, and the second adhesive layer AL-2 may include or consist of the low hardness adhesive COP-2 to be in a flexible state. Accordingly, when the preliminary first adhesive layer P_AL-1 and the second adhesive layer AL-2 are provided on the display module DM, the preliminary first adhesive layer P_AL-1 and the second adhesive layer AL-2 may be in close contact with a surface of the display module DM to fill a curve of the surface. Further, the non-uniform gap formed between the synthetic resin film FL and the display module DM may be uniformly coated, and the synthetic resin film FL and the display module DM may adhere to each other.

The electronic device manufactured by the method of manufacturing an electronic device in an embodiment may exhibit improved display quality. The electronic device, which is manufactured by the method of manufacturing an electronic device including an operation of providing the adhesive layer on the display module after the adhesive layer is completely cured, does not resolve the surface defect of the display module and exhibits relatively low display quality. Unlike this, in the electronic device that is manufactured by the method of manufacturing an electronic device including an operation of completely curing the preliminary first adhesive layer P_AL-1 in a semi-cured state after the preliminary first adhesive layer P_AL-1 is provided on the display module DM, the surface curve of the display module DM may be filled, the non-uniform gap between the synthetic resin film FL and the display module DM may be resolved, and thus excellent surface quality and excellent display quality may be exhibited.

The method of manufacturing an electronic device method in an embodiment including an operation of providing the preliminary window member P_WM on the display module DM may exhibit excellent manufacturing efficiency. The method of manufacturing an electronic device including an operation of providing the synthetic resin film and the adhesive to the display module has a long process time and exhibits relatively low manufacturing efficiency. Unlike this, the method of manufacturing an electronic device in an embodiment may exhibit excellent manufacturing efficiency through an operation of manufacturing the synthetic resin film FL and the adhesives COP-1 and COP-2 as an integrated film and providing the integrated film to the display module DM.

Although not illustrated, the lower module LM (refer to FIG. 5) may be further disposed under the display module DM. Further, although not illustrated, the protective layer PL (refer to FIG. 5) and the upper adhesive layer P-AL (refer to FIG. 5) may be provided on the preliminary window member P_WM. The display module DM, the preliminary window member P_WM, and the protective layer PL (refer to FIG. 5) may be coupled through a lamination process.

Referring to FIGS. 13G and 13H, second light LL2 may be provided to the preliminary window member P_WM. In FIGS. 13D and 13G, the first light LL1 and the second light LL2 may be ultraviolet light. However, this is one of the embodiments, and the disclosure is not limited thereto.

The preliminary window member P_WM may be cured by the second light LL2 to form the window member WM. The preliminary first adhesive layer P_AL-1 may be cured by the second light LL2 to form the first adhesive layer AL-1. The first adhesive layer AL-1 may be in a completely cured state. In this case, components (e.g., the second adhesive layer AL-2, the synthetic resin film FL, or the like) except the preliminary first adhesive layer P_AL-1 may not be affected by changes in physical properties by the second light LL2.

It is illustrated in FIGS. 13A to 13H that the post-curable adhesive COP-1 is cured twice (i.e., cured by providing light twice) to form the first adhesive layer AL-1, but the disclosure is not limited thereto. In an embodiment, the post-curable adhesive COP-1 may be cured three or more times to form the first adhesive layer AL-1, for example.

It is illustrated in FIGS. 13A to 13H that the operation of providing the post-curable adhesive COP-1 is performed after the operation of providing the low hardness adhesive COP-2, but the disclosure is not limited thereto. The operation of providing the low hardness adhesive COP-2 may be performed after the operation of providing the post-curable adhesive COP-1. Further, the post-curable adhesive COP-1 may include a first sub-post-curable adhesive and a second sub-post-curable adhesive, the operation of providing the low hardness adhesive COP-2 may be performed after an operation of providing the first sub-post-curable adhesive, and an operation of providing the second sub-post-curable adhesive may be performed after the operation of providing the low hardness adhesive COP-2.

The method of manufacturing an electronic device in an embodiment may include an operation of forming the preliminary window member. Further, the method may include an operation of forming the window member by providing the preliminary window member onto the display module and then radiating light. The electronic device in an embodiment, which is formed by the method of manufacturing an electronic device in an embodiment, may include the synthetic resin film, the first adhesive layer including the post-curable adhesive, and the second adhesive layer including the low hardness adhesive having a lower hardness than that of the post-curable adhesive, thereby exhibiting excellent display quality. Further, the electronic device in an embodiment may exhibit characteristics that facilitate folding, rolling, or sliding.

An electronic device in an embodiment may include a synthetic resin film, a first adhesive layer including a post-curable adhesive, and a second adhesive layer including a low hardness adhesive having a smaller hardness than the post-curable adhesive, thereby exhibiting excellent folding, rolling, and sliding reliability and excellent display quality.

A method of manufacturing an electronic device in an embodiment may include an operation of forming a window member by photo-curing a preliminary window member provided on a display module, thereby exhibiting excellent manufacturing efficiency and excellent processability.

Although the description has been made above with reference to an embodiment of the disclosure, it may be understood that those skilled in the art or those having ordinary knowledge in the art may variously modify and change the disclosure without departing from the spirit and technical scope of the disclosure described in the appended claims.

Accordingly, the technical scope of the disclosure is not limited to the detailed description of the specification, but should be defined by the appended claims.

What is claimed is:

1. An electronic device comprising:
a display module including:
a deformation part which is foldable, rollable, or slidable; and
a non-deformation part next to the deformation part; and
a window member disposed on the display module, the window member including:
a synthetic resin film; and
a first adhesive layer and a second adhesive layer arranged between the display module and the synthetic resin film,
wherein the first adhesive layer includes a post-curable adhesive and has a Young's modulus of 0.1 megapascal to 1 megapascal at a room temperature, and
wherein the second adhesive layer includes a low hardness adhesive having a hardness smaller than a hardness of the post-curable adhesive.

2. The electronic device of claim 1, wherein surface quality is smaller than or equal to 0.3.

3. The electronic device of claim 1, wherein the synthetic resin film has a Young's modulus of 0.5 gigapascal to 10 gigapascals at the room temperature.

4. The electronic device of claim 1, wherein the synthetic resin film includes at least one of an acrylic resin, an epoxy resin, and a siloxane resin.

5. The electronic device of claim 1, wherein a crosslinking degree of the first adhesive layer is greater than or equal to 90%.

6. The electronic device of claim 1, wherein the second adhesive layer has a Young's modulus of 0.01 megapascal to 0.1 megapascal at the room temperature.

7. The electronic device of claim 1, wherein the synthetic resin film is disposed on the first adhesive layer, and
wherein the first adhesive layer is disposed on the second adhesive layer.

8. The electronic device of claim 1, wherein the synthetic resin film is disposed on the second adhesive layer, and
wherein the second adhesive layer is disposed on the first adhesive layer.

9. The electronic device of claim 1, wherein the second adhesive layer includes a first sub-adhesive layer and a second sub-adhesive layer,
wherein the synthetic resin film is disposed on the first sub-adhesive layer,
wherein the first sub-adhesive layer is disposed on the first adhesive layer, and
wherein the first adhesive layer is disposed on the second sub-adhesive layer.

10. The electronic device of claim 1, wherein the synthetic resin film contacts the first adhesive layer or the second adhesive layer, and the first adhesive layer and the second adhesive layer contact each other.

11. The electronic device of claim 1, wherein the window member has a thickness of 25 micrometers to 100 micrometers.

12. The electronic device of claim 1, further comprising:
at least one of a processor, a memory, and a power module.

13. A method of manufacturing an electronic device, the method comprising:
preparing a display module including a deformation part which is foldable, rollable, or slidable and a non-deformation part next to the deformation part;
forming a preliminary window member including a synthetic resin film, a first preliminary adhesive layer, and a second adhesive layer;
providing the preliminary window member onto the display module; and
forming a window member including the synthetic resin film, a first adhesive layer, and the second adhesive layer by radiating second light to the preliminary window member,
wherein the forming the preliminary window member includes:
preparing a substrate;
providing a post-curable adhesive and a low hardness adhesive having a hardness smaller than a hardness of the post-curable adhesive onto the substrate;
providing the synthetic resin film onto the post-curable adhesive and the low hardness adhesive; and
forming the first preliminary adhesive layer and the second adhesive layer by radiating first light to the post-curable adhesive and the low hardness adhesive,
wherein the first adhesive layer includes the post-curable adhesive and has a Young's modulus of 0.1 megapascal to 1 megapascal at a room temperature, and
wherein the second adhesive layer includes the low hardness adhesive.

14. The method of claim 13, wherein the providing the post-curable adhesive is performed after the providing the low hardness adhesive.

15. The method of claim 13, wherein the providing the low hardness adhesive is performed after the providing the post-curable adhesive.

16. The method of claim 13, wherein the post-curable adhesive includes a first sub-post-curable adhesive and a second sub-post-curable adhesive,
wherein the providing the low hardness adhesive is performed after providing the first sub-post-curable adhesive, and
wherein providing the second sub-post-curable adhesive is performed after the providing the low hardness adhesive.

17. The method of claim 13, wherein the synthetic resin film contacts the first adhesive layer or the second adhesive layer, and the first adhesive layer and the second adhesive layer contact each other.

18. The method of claim 13, wherein the synthetic resin film has a Young's modulus of 0.5 gigapascal to 10 gigapascals at the room temperature.

19. The method of claim 13, wherein a crosslinking degree of the first adhesive layer is greater than or equal to 90%.

20. The method of claim 13, wherein the second adhesive layer has a Young's modulus of 0.01 megapascal to 0.1 megapascal at the room temperature.
